(19) United States
(12) Patent Application Publication
(10) Pub. No.: US 2016/0093617 A1
(43) Pub. Date: Mar. 31, 2016

(54) SEMICONDUCTOR DEVICE HAVING WORK FUNCTION CONTROL LAYER AND METHOD OF MANUFACTURING THE SAME

(71) Applicants: Jung-Min PARK, Seoul (KR); Suk-Hoon KIM, Yongin-si (KR); Min-Woo SONG, Seongnam-si (KR); Seok-Jun WON, Seoul (KR); In-Hee LEE, Suwon-si (KR); Kyung-Il HONG, Suwon-si (KR); Sang-Jin HYUN, Suwon-si (KR)

(72) Inventors: Jung-Min PARK, Seoul (KR); Suk-Hoon KIM, Yongin-si (KR); Min-Woo SONG, Seongnam-si (KR); Seok-Jun WON, Seoul (KR); In-Hee LEE, Suwon-si (KR); Kyung-Il HONG, Suwon-si (KR); Sang-Jin HYUN, Suwon-si (KR)

(21) Appl. No.: 14/635,253

(22) Filed: Mar. 2, 2015

(30) Foreign Application Priority Data
Sep. 30, 2014 (KR) 10-2014-0131670

(51) Int. Cl. H01L 27/092; H01L 29/51; H01L 29/423; H01L 29/49

(52) U.S. Cl. CPC H01L 27/0922; H01L 29/4966; H01L 29/4975; H01L 29/511; H01L 29/42364; H01L 29/42376

(57) ABSTRACT

A semiconductor device, including a substrate; an interlayer insulating layer having a trench on the substrate, the trench having a bottom and sidewalls; a dielectric layer on the bottom and sidewalls of the trench; a work function control layer on the dielectric layer; a wetting layer on the work function control layer; a gap fill layer on the wetting layer; and a reactive layer between the wetting layer and the gap fill layer, the reactive layer being thicker than the gap fill layer.

### CROSS-REFERENCE TO RELATED APPLICATION

Korean Patent Application No. 10-2014-0131670, filed on Sep. 30, 2014, in the Korean Intellectual Property Office, and entitled: “Semiconductor Device Having Work Function Control Layer and Method of Manufacturing the Same,” is incorporated by reference herein in its entirety.

### BACKGROUND

1. Field

Example embodiments relate to a semiconductor device having a work function control layer, and to a method of manufacturing the same.

2. Description of the Related Art

To increase performance of semiconductor devices having highly integrated circuits, metal gate electrodes may be used with a high-k dielectric layer instead of polysilicon gate electrodes in the semiconductor device. The metal gate electrodes may be formed by using a replacement metal gate (RMG) process.

### SUMMARY

Embodiments may be realized by providing a semiconductor device, including a substrate; an interlayer insulating layer having a trench on the substrate, the trench having a bottom and sidewalls; a dielectric layer on the bottom and sidewalls of the trench; a work function control layer on the dielectric layer; a wetting layer on the work function control layer; a gap fill layer on the wetting layer; and a reactive layer between the wetting layer and the gap fill layer, the reactive layer being thicker than the gap fill layer.

The wetting layer may include titanium (Ti) and the gap fill layer may include aluminum (Al).

The reactive layer may include titanium aluminum (TiₓAl_{y}).

The reactive layer may include one or more of TiAl, TiAl₃, TiAlO, or TiAlN.

The work function control layer may include an N-type work function control layer.

The semiconductor device may further include an interface layer between the substrate and the dielectric layer.

Embodiments may be realized by providing a semiconductor device, including a first device; and a second device, the first device including a first interlayer insulating layer having a first trench, the first trench having a bottom and sidewalls; a first dielectric layer on the bottom and sidewalls of the first trench; a first work function control layer on the first dielectric layer; a first wetting layer on the first work function control layer; a gap fill layer on the first wetting layer; and a first reactive layer between the first wetting layer and the gap fill layer, the first reactive layer being formed by a reaction of the first wetting layer and the gap fill layer; the second device including a second interlayer insulating layer having a second trench, the second trench having a bottom and sidewalls; a second dielectric layer on the bottom and sidewalls of the second trench; a second work function control layer on the second dielectric layer; a second wetting layer on the second work function control layer; and a second reactive layer on the second wetting layer.

The first and second wetting layers may include titanium (Ti); and the gap fill layer may include aluminum (Al).

The first and second reactive layers may include titanium aluminum (TiₓAl_{y}).

The first and second reactive layers may include one or more of TiAl, TiAl₃, TiAlO, or TiAlN.

The semiconductor device may further include a third work function control layer between the second dielectric layer and the second work function control layer.

The first and second work function control layers may be N-type work function control layers; and the third work function control layer may be a P-type work function layer.

The first work function control layer may be an N-type work function control layer; and the second work function control layer may be a P-type work function layer.

The first reactive layer may be thicker than the gap fill layer.

The first device may be a N-type metal-oxide semiconductor (NMOS) and the second device may be a P-type metal-oxide semiconductor (PMOS).

Embodiments may be realized by providing a method of manufacturing a semiconductor device, the method including forming an interlayer insulating layer having a trench on a substrate, the trench having a bottom and sidewalls; forming a dielectric layer on the bottom and sidewalls of the trench; forming a work function control layer on the dielectric layer; forming a wetting layer on the work function control layer; and forming a reactive layer and a gap fill layer on the wetting layer to fill the trench, the reactive layer being thicker than the gap fill layer.

Forming the reactive layer and the gap fill layer may include forming a first portion of the gap fill layer on the wetting layer; performing a first heat treatment to form the reactive layer; forming a second portion of the gap fill layer on the reactive layer; and performing a second heat treatment.

Forming the first portion of the gap fill layer, performing the first heat treatment, forming the second portion of the gap fill layer, and performing the second heat treatment may be performed in-situ.

The first and second heat treatments may be performed in substantially a same temperature range.

A first temperature range of forming the first portion of the gap fill layer may be less than a second temperature range of performing the first heat treatment, forming the second portion of the gap fill layer, or performing the second heat treatment.

A first temperature range of performing the first heat treatment may be greater than a second temperature range of performing the second heat treatment.

A first process time of performing the first heat treatment may be longer than a second process time of performing the second heat treatment.

The first portion of the gap fill layer may be thinner than the second portion of the gap fill layer.

Forming the wetting layer may include forming a first portion of the wetting layer using a direct current (DC); and forming a second portion of the wetting layer using an alternating current (AC).

A power ratio of the DC to the AC may be greater than 0 but less than 1.

A deposition time ratio of the DC to the AC may be greater than 0 but less than 3.

Embodiments may be realized by providing a method of manufacturing a semiconductor device, the method including forming an interlayer insulating layer having a trench on a substrate, the trench having a bottom and sidewalls; forming a high-k dielectric layer on the bottom and sidewalls of the trench; forming an N-type work function control layer on the high-k dielectric layer; forming a wetting layer including titanium (Ti) on the N-type work function control layer; forming a first gap fill layer including aluminum (Al) on the wetting layer; performing a first heat treatment on the first gap fill layer to form a reactive layer; forming a second gap fill layer including aluminum (Al) on the reactive layer; performing a second heat treatment on the second gap fill layer; and performing a planarization process to expose an upper surface of the interlayer insulating layer.

The method may further include forming a reactive layer by performing the first heat treatment.

The reactive layer may include titanium aluminum (TiₓAl_{y}).

The reactive layer may include one or more of TiAl, TiAl₃, TiAlO, or TiAlN.

Embodiments may be realized by providing a method of manufacturing a semiconductor device, the method including forming an interlayer insulating layer having a trench on a substrate, the trench having a bottom and sidewalls; forming a dielectric layer on the bottom and sidewalls of the trench, the dielectric layer having a dielectric constant greater than that of a silicon oxide layer; forming a work function control layer on the dielectric layer; forming a wetting layer on the work function control layer; forming a gap fill layer on the wetting layer; and performing a heat treatment to form a reactive layer by a chemical reaction between the wetting layer and the gap fill layer, the reactive layer preventing aluminum from diffusing into the dielectric layer from the gap fill layer.

The reactive layer may include titanium aluminum (TiₓAl_{y}).

The reactive layer may include one or more of TiAl, TiAl₃, TiAlO, or TiAlN.

Embodiments may be realized by providing a semiconductor device, including an interlayer insulating layer having a trench on a substrate, the trench having a bottom and sidewalls; a dielectric layer on the bottom and sidewalls of the trench, the dielectric layer having a dielectric constant greater than that of a silicon oxide layer; a work function control layer on the dielectric layer; a wetting layer on the work function control layer; a gap fill layer on the wetting layer; and a reactive layer between the wetting layer and the gap fill layer, the reactive layer including a first material included in the wetting layer and a second material included in the gap fill layer.

The first material may be titanium (Ti) and the second material may be aluminum (Al).

The reactive layer may include titanium aluminum (TiₓAl_{y}).

The reactive layer may include one or more of TiAl, TiAl₃, TiAlO, or TiAlN.

The reactive layer may be a diffusion preventing layer preventing aluminum from diffusing into the dielectric layer from the gap fill layer.

### BRIEF DESCRIPTION OF THE DRAWINGS

Features will become apparent to those of skill in the art by describing in detail exemplary embodiments with reference to the attached drawings in which:

FIG. 1 illustrates a layout of a semiconductor device according to a first example embodiment;

FIG. 2 illustrates a cross-sectional view corresponding to line A-A of FIG. 1;

FIG. 3 illustrates a cross-sectional view corresponding to line B-B of FIG. 1;

FIG. 4 illustrates a cross-sectional view corresponding to line C-C of FIG. 1;

FIG. 5 illustrates a cross-sectional view of a semiconductor device according to a second example embodiment;

FIG. 6 illustrates a cross-sectional view of a semiconductor device according to a third example embodiment;

FIG. 7 illustrates a cross-sectional view of a semiconductor device according to a fourth example embodiment;

FIGS. 8A and 8B illustrate cross-sectional views of a semiconductor device according to a fifth example embodiment;

FIG. 9 illustrates a perspective view of a semiconductor device according to a sixth example embodiment;

FIG. 10 illustrates a cross-sectional view corresponding to line E-E of FIG. 9;

FIG. 11 illustrates a cross-sectional view corresponding to line D-D of FIG. 9;

FIGS. 12 through 20 illustrate cross-sectional views of a method of manufacturing a semiconductor device according to the first example embodiment;

FIGS. 21 through 26 illustrate cross-sectional views of a method of manufacturing a semiconductor device according to the fifth example embodiment;

FIG. 27 illustrates a block diagram of a memory card including a semiconductor device according to an example embodiment;

FIG. 28 illustrates a block diagram of an information processing system including a semiconductor device according to an example embodiment; and

FIG. 29 illustrates a block diagram of an electronic device including a semiconductor device according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

It will be understood that when an element is referred to as being “on” or “connected” to another element, it can be directly on, connected or coupled to the other element or intervening elements may be present.

It will be understood that, although the terms “first”, “second”, etc., may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section. Thus, a first element, component, region, layer or section discussed below could be termed a second element, component, region, layer or section without departing from the teachings of example embodiments.

In the figures, the dimensions of layers and regions may be exaggerated for clarity of illustration. Like reference numerals refer to like elements throughout.

Spatially relative terms, e.g., “lower,” “above,” “upper” and the like, may be used herein for ease of description to describe the relationship of one element or feature to another element(s) or feature(s), as illustrated in the figures. It will be understood that the spatially relative terms are intended to encompass different orientations of the device in use or operation in addition to the orientation depicted in the figures. For example, if the device in the figures is turned over, elements described as “lower” relative to other elements or features would then be oriented above the other elements or features. Thus, the exemplary term “lower” can encompass both an orientation of above and below. The device may be otherwise oriented (rotated 90 degrees or at other orientations) and the spatially relative descriptors used herein interpreted accordingly.

As used herein, the term “and/or” includes any and all combinations of one or more of the associated listed items. The use of the terms “a” and “an” and “the” and similar referents in the context of describing embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to”) unless otherwise noted.

Unless defined otherwise, all technical and scientific terms used herein have the same meaning as commonly understood by one of skill in the art. It is noted that the use of any and all examples, or exemplary terms provided herein is intended merely to better illuminate the example embodiments and is not intended to be limiting unless otherwise specified.

Example embodiments will be described with reference to perspective views, cross-sectional views, and/or plan views. The profile of an example view may be modified according to, e.g., manufacturing techniques and/or allowances. Accordingly, the example embodiments are not intended to limit the scope, but cover all changes and modifications that can be caused due to, e.g., a change in manufacturing process. Thus, regions shown in the drawings are illustrated in schematic form and the shapes of the region are presented simply by way of illustration and not as a limitation.

Unless the context indicates otherwise, terms such as “same,” “equal,” or “planar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Hereinafter, exemplary embodiments will be described in detail with reference to the accompanying drawings.

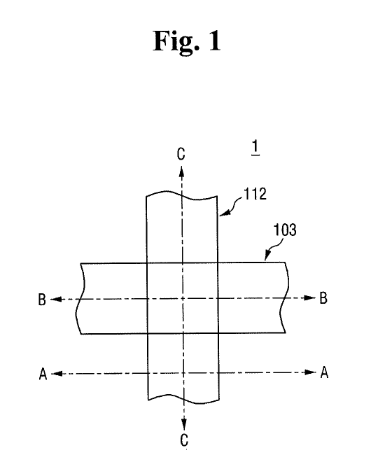

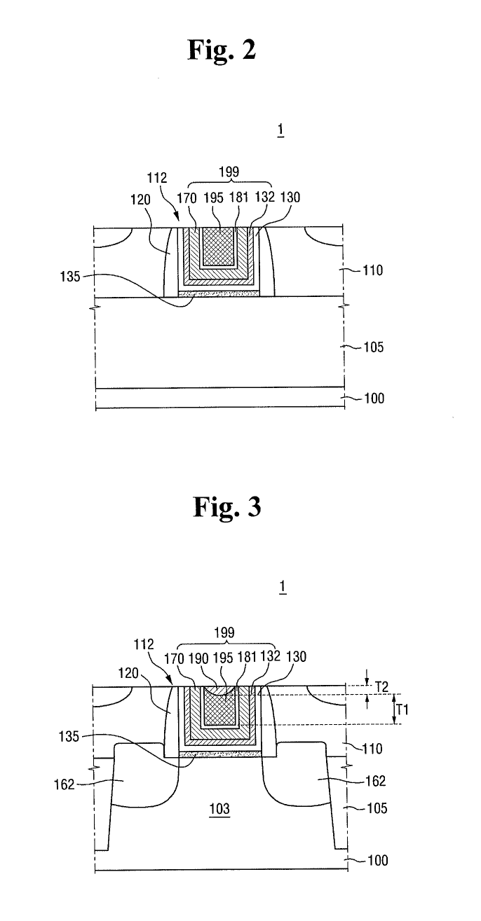

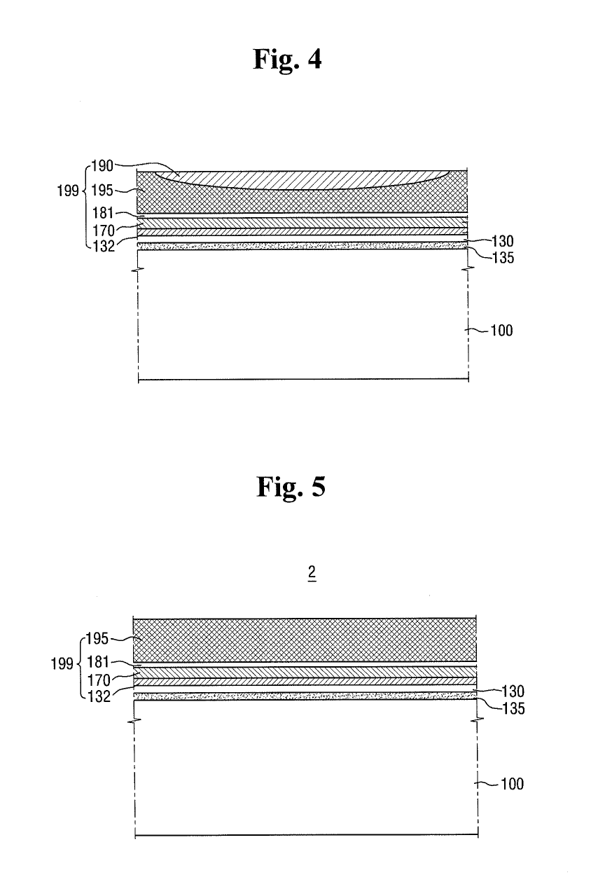

FIG. 1 illustrates a layout of a semiconductor device according to a first example embodiment. FIG. 2 illustrates a cross-sectional view corresponding to line A-A of FIG. 1. FIG. 3 illustrates a cross-sectional view corresponding to line B-B of FIG. 1. FIG. 4 illustrates a cross-sectional view corresponding to line C-C of FIG. 1. The semiconductor device shown in FIG. 1 may include an N-type transistor.

Referring to FIGS. 1 through 4, a semiconductor device 1 according to the first example embodiment may include a substrate 100, a device isolation region 105, an interlayer insulating layer 110 having a first trench 112, a first interface layer 135, a first dielectric layer 130, and a first metal gate electrode 199. The first metal gate electrode 199 may include a lower metal layer 132, an N-type work function control layer 170, a first wetting layer 181, a first reactive layer 195, and a first gap fill layer 190. The first metal gate electrode 199 may be formed by using a replacement metal gate (RMG) process.

An active region 103 may be defined by forming the device isolation region 105, e.g., a shallow trench isolation (STI), in the substrate 100. The active region 103 may extend to a first direction, e.g., B-B direction as shown in FIG. 1. The substrate 100 may include one or more of silicon (Si), germanium (Ge), silicon germanium (SiGe), gallium phosphide (GaP), gallium arsenide (GaAs), silicon carbide (SiC), silicon germanium carbide (SiGeC), Indium arsenide (InAs), or indium phosphide (InP). The substrate 100 may be a silicon-on-insulator (SOI) substrate.

The interlayer insulating layer 110 having the first trench 112 may be formed on the substrate 100. The interlayer insulating layer 110 may be formed by laminating at least two or more insulating layers. Sidewalls of the first trench 112 may contact a spacer 120 and a bottom of the first trench 112 may contact the substrate 100. The first trench 112 may cross the active region 103 and may extend to a second direction, e.g., C-C direction as shown in FIG. 1. The first trench 112 may expose a portion of the device isolation region 105 and a portion of the active region 103. The spacer 120 may include one or more of silicon nitride or silicon oxynitride.

The first interface layer 135 may be formed in the first trench 112. The first interface layer 135 may be formed at a bottom of the first trench 112 by using an oxidation process. In an embodiment, the first interface layer 135 may be conformally formed at the bottom and sidewalls of the first trench 112 by using a deposition process, e.g., a chemical vapor deposition (CVD) process or an atomic layer deposition (ALD) process.

The first interface layer 135 may be a silicon oxide layer, e.g., a high temperature oxide (HTO) layer. The interface layer 135 may have a thickness of about 5 angstrom to about 50 angstrom. For example, the thickness of the interface layer 135 may be about 10 angstrom. The interface layer 135 may increase operating characteristics, e.g., breakdown voltage (BV) characteristic, of a high voltage transistor.

The first dielectric layer 130 may be formed on the first interface layer 135. The first dielectric layer 130 may be conformally formed along the sidewalls and the bottom of the first trench 112. The first dielectric layer 130 may include a high-k dielectric layer having a dielectric constant greater than that of a silicon oxide layer. For example, the first dielectric layer 130 may include one or more of hafnium oxide (HfO₂), zirconium oxide (ZrO₂), tantalum oxide (Ta₂O₅), titanium oxide (TiO₂), strontium titanate (SrTiO₃), or barium titanate (BaTiO₃). The first dielectric layer 130 may have various thicknesses according to the material thereof. For example, if the material of the first dielectric layer 130 is hafnium oxide (HfO₂), the thickness of the first dielectric layer 130 may be about 5 angstrom to about 50 angstrom.

The lower metal layer 132 may be formed on the first dielectric layer 130. The lower metal layer 132 may be conformally formed along the sidewalls and the bottom of the first trench 112. The lower metal layer 132 may include one or more of titanium nitride (TiN) or tantalum nitride (TaN).

The N-type work function control layer 170 may be formed on the lower metal layer 132 in the first trench 112. The N-type work function control layer 170 may be conformally formed along the sidewalls and the bottom of the first trench 112. The N-type work function control layer 170 may include one or more of titanium aluminum (TiAl), tantalum aluminum carbide (TaAlC), titanium aluminum nitride (TiAlN), tantalum carbide (TaC), or hafnium silicon (HIEi).

The first wetting layer 181 may be formed on the N-type work function control layer 170 in the first trench 112. The first wetting layer 181 may include titanium nitride (TiN) and/or titanium (Ti). For example, if the first gap fill layer 190 is an aluminum (Al) layer, the first wetting layer 181 may be a single layer which may be formed of titanium nitride (TiN) or titanium (Ti). In an embodiment, the first gap fill layer 190 may be a tungsten (W) layer, and the first wetting layer 181 may be a single layer which may be formed of titanium nitride (TiN). The first wetting layer 181 may have a thickness of about 10 angstrom to about 100 angstrom.

The first reactive layer 195 may be formed between the first wetting layer 181 and the first gap fill layer 190. The first reactive layer 195 may be a reactant which may be formed by a chemical reaction between the first wetting layer 181 and the first gap fill layer 190. The reactant may be formed by a heat treatment. For example, if the first wetting layer 181 includes titanium (Ti) and the first gap fill layer includes aluminum (Al), the first reactive layer 195 may include titanium aluminum (TiₓAl_{y}, x and y are natural numbers). For example, the first reactive layer 195 may include one or more of TiAl, TiAl₃, TiAlO, or TiAlN.

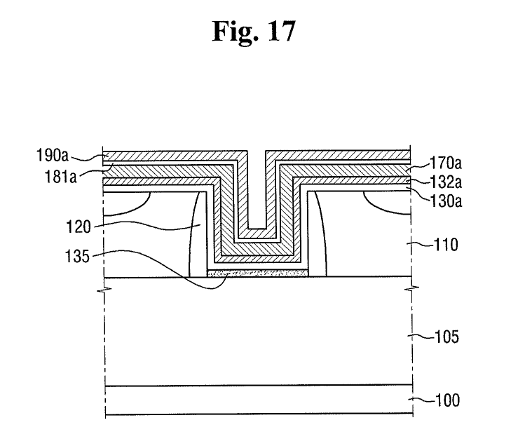

The first reactive layer 195 may prevent an element of the first gap fill layer 190, e.g., aluminum (Al), from penetrating, e.g., diffusing, into the first dielectric layer 130. The first reactive layer 195 may be formed by at least one heat treatment after forming the first gap fill layer 190. An example method of forming the first reactive layer 195 will be described later referring to FIGS. 17 through 20 in detail. Due to formation of the first reactive layer 195, it may not be necessary to form a thick barrier metal layer, and a thinner barrier metal layer may be formed, or, in an embodiment, the operation of forming a barrier metal layer may be omitted.

A first thickness T1 of the first reactive layer 195 may be thicker than a second thickness T2 of the first gap fill layer 190 as shown in FIG. 3. For example, the first thickness T1 may be about 300 angstrom to about 500 angstrom. The first gap fill layer 190 may not directly contact the first wetting layer 181 because of the first reactive layer 195 which may be formed between the first wetting layer 181 and the first gap fill layer 190. For example, the first reactive layer 195 may be formed along the bottom as well as the sidewalls of the first trench 112.

The first gap fill layer 190 may extend to a longitudinal direction of the first metal gate electrode 199. Almost all the portion of the first gap fill layer 190 which does not react with the first wetting layer 181 may be removed by a planarization process, e.g., a chemical mechanical polishing (CMP) process. After the planarization process, a little, e.g., small, portion of the first gap fill 190 layer may remain on the first reactive layer 195, and if the semiconductor device 1 is cut along a width direction of the metal gate electrode 199, a portion of the first gap fill layer 190 may remain as shown in FIG. 3, or may not remain as shown in FIG. 2.

FIG. 5 illustrates a cross-sectional view of a semiconductor device according to a second example embodiment. For convenience of explanation, some of descriptions which are substantially the same as those corresponding to the first example embodiment mentioned above will be omitted.

Referring to FIG. 5, the first gap fill layer 190 may not remain in the first metal gate electrode 199 of a semiconductor device 2 according to the second example embodiment. For example, the first reactive layer 195 may be formed by an efficient reaction between the first wetting layer 181 and the first gap fill layer 190 and almost all of an unreacted portion of the first gap fill layer 190 may be removed by performing a planarization process, and the first trench 112 may be filled by the first reactive layer 195.

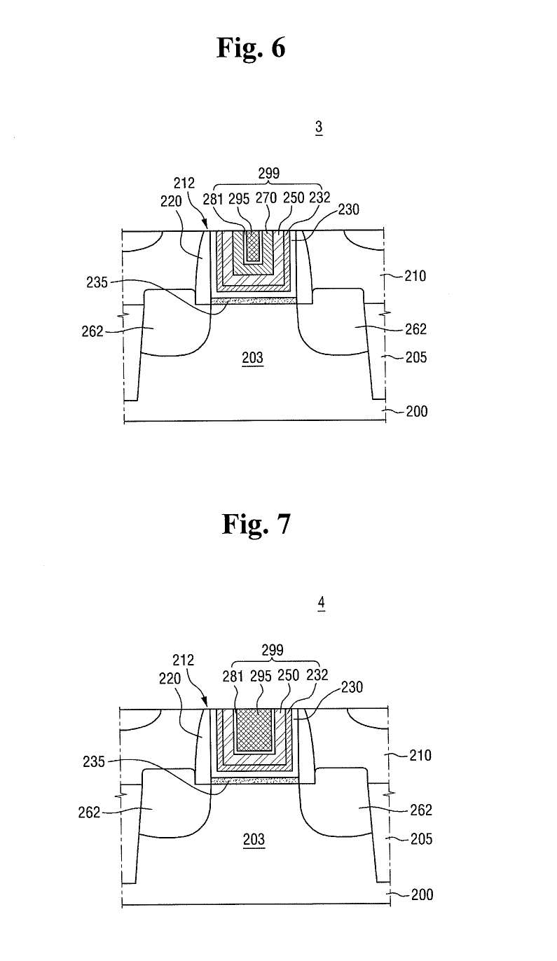

FIG. 6 illustrates a cross-sectional view of a semiconductor device according to a third example embodiment. For convenience of explanation, some of descriptions which are substantially the same as those corresponding to the first example embodiment mentioned above will be omitted.

Referring to FIG. 6, a semiconductor device 3 according to the third example embodiment may include a substrate 200, a device isolation region 205, an interlayer insulating layer 210 having a second trench 212, a second interface layer 235, a second dielectric layer 230, and a second metal gate electrode 299. The second metal gate electrode 299 may include a lower metal layer 232, a P-type work function control layer 250, an N-type work function control layer 270, a second wetting layer 281, and a second reactive layer 295. The second metal gate electrode 299 may be formed by using a replacement metal gate (RMG) process.

The second interface layer 235 may be formed in the second trench 212. The second interface layer 235 may be formed on a bottom of the second trench 212 by performing an oxidation process. The second interface layer 235 may be conformally formed along the sidewalls and the bottom of the second trench 212, differently as shown in FIG. 6, by using a deposition process.

The second dielectric layer 230 may be formed on the first interface layer 235. The second dielectric layer 230 may be conformally formed along the sidewalls and the bottom of the second trench 212.

The lower metal layer 232 may be formed on the second dielectric layer 230. The lower metal layer 232 may be conformally formed along the sidewalls and the bottom of the second trench 212. The lower metal layer 232 may include one or more of titanium nitride (TiN) or tantalum nitride (TaN). The lower metal layer 232 may be a stacked structure of combination of a titanium nitride (TiN) layer and a tantalum nitride (TaN) layer.

The P-type work function control layer 250 may be formed on the lower metal layer 232 formed in the second trench 212. In an embodiment, the P-type work function control layer 250 may be conformally formed along the sidewalls and the bottom of the second trench 212. The P-type work function control layer 250 may include titanium nitride (TiN).

The N-type work function control layer 270 may be formed on the P-type work function layer 250. The N-type work function control layer 270 may remain in a P-type metal-oxide semiconductor (PMOS) transistor, if the N-type work function control layer 270 may not significantly decrease any performance of the PMOS transistor.

The second wetting layer 281 may be formed on the N-type work function control layer 270 in the second trench 212. The second wetting layer 281 may include titanium nitride (TiN) and/or titanium (Ti).

The second reactive layer 295 may be formed on the second wetting layer 281. The second reactive layer 295 may be a reactant which may be formed by a chemical reaction between the second wetting layer 281 and the second gap fill layer which may be formed on the second wetting layer at the following operation. The reactant may be formed by a heat treatment. For example, if the second wetting layer 281 includes titanium (Ti) and the second gap fill layer includes aluminum (Al), the second reactive layer 295 may include titanium aluminum (TiₓAl_{y}, x and y are natural numbers). For example, the second reactive layer 295 may include one or more of TiAl, TiAl₃, TiAlO, or TiAlN.

Because the second metal gate electrode 299 includes the N-type work function control layer 270 and the P-type work function control layer 250, a gap fill region on the second wetting layer 281 in the second trench 212 may be smaller, and the second reactive layer 295 may wholly, e.g., completely, fill the second trench 212. In an embodiment, almost all the portion of the second gap fill layer which does not react with the second wetting layer 281 may be removed by a planarization process, e.g., a chemical mechanical polishing (CMP) process, and the second gap fill layer may not remain in the final structure of the second metal gate electrode 299.

FIG. 7 illustrates a cross-sectional view of a semiconductor device according to a fourth example embodiment. For convenience of explanation, some of descriptions which are substantially the same as those corresponding to the third example embodiment mentioned above will be omitted.

Referring to FIG. 7, a semiconductor device 4 according to the fourth example embodiment may not include the N-type work function control layer (see reference number 270 in FIG. 6). If the semiconductor device 4 is a PMOS transistor, the N-type work function control layer may be removed from the second metal gate electrode 299 to increase the performance of the PMOS transistor, and the second gap fill layer may remain on the second reactive layer 295 after the planarization process. In an embodiment, the second gap fill layer may not remain on the second reactive layer 295.

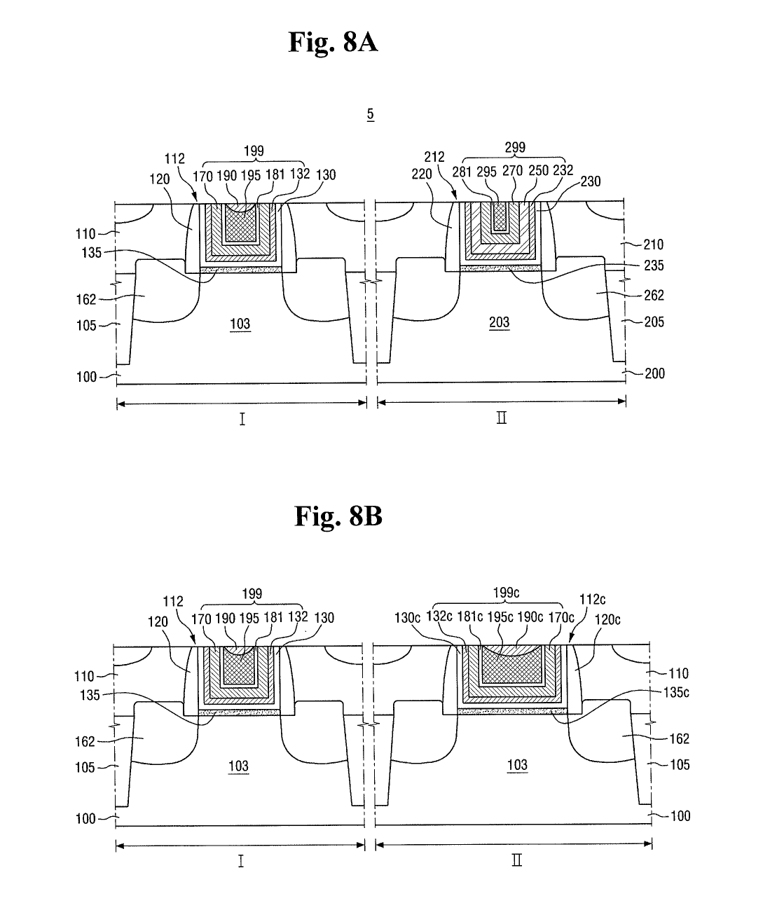

FIG. 8A illustrates a cross-sectional view of a semiconductor device according to a fifth example embodiment. Referring to FIG. 8A, a semiconductor device 5 according to the fifth example embodiment may include a first substrate 100 in a first region I and a second substrate 200 in a second region II. One of the N-type metal-oxide semiconductor (NMOS) transistors which are mentioned above referring to FIGS. 1 through 5 may be formed in the first region I and one of the PMOS transistors which are mentioned above referring to FIGS. 6 and 7 may be formed in the second region II.

For example, the NMOS transistor shown in FIG. 3 may be formed in the first region I and the PMOS transistor shown in FIG. 6 may be formed in the second region II, and the first gap fill layer 190 may remain on the first reactive layer 195 and the second gap fill layer may not remain on the second reactive layer 295.

Alternatively, although not shown separately, an NMOS transistor formed in the first region I may not include the first gap fill layer on the first reactive layer 195 (see FIG. 5) and a PMOS transistor formed in the second region II may not include the second gap fill layer on the second reactive layer 295.

Alternatively, although not shown separately, an NMOS transistor formed in the first region I may include the first gap fill layer (see FIGS. 3 and 4) on the first reactive layer 195 and a PMOS transistor formed in the second region II may include the second gap fill layer on the second reactive layer 295.

FIG. 8B illustrates a cross-sectional view of a semiconductor device according to an example embodiment. Referring to FIG. 8B, a short channel transistor may be formed in the first region I and a long channel transistor may be formed in the second region II. The long channel transistor may have substantially the same structure with the short channel transistor. The long channel transistor may include an interface layer 135c, a dielectric layer 130c, and a metal gate electrode 199c. The metal gate electrode 199c may include a lower metal layer 132c, an N-type work function control layer 170c, a wetting layer 181c, a reactive layer 195c, and a gap fill layer 190c.

As mentioned above, the reactive layers 195 and 195c may be formed by performing at least one heat treatment. The reactive layer 195c formed in the long channel transistor may also prevent an element of the gap fill layer 190c, e.g., aluminum (Al), from penetrating, e.g., diffusing, into the dielectric layer 130c.

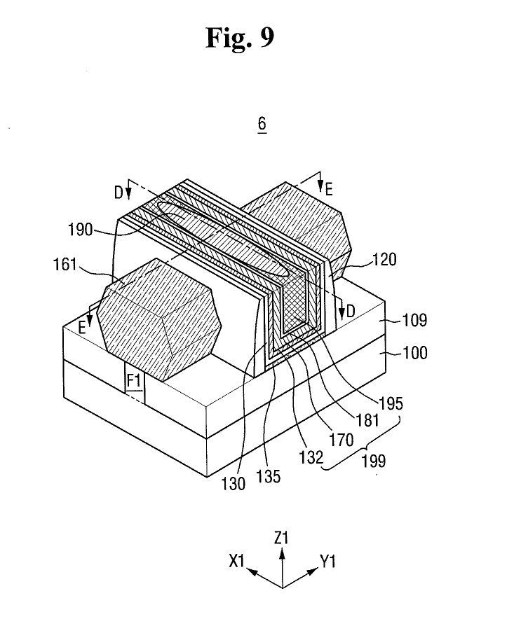

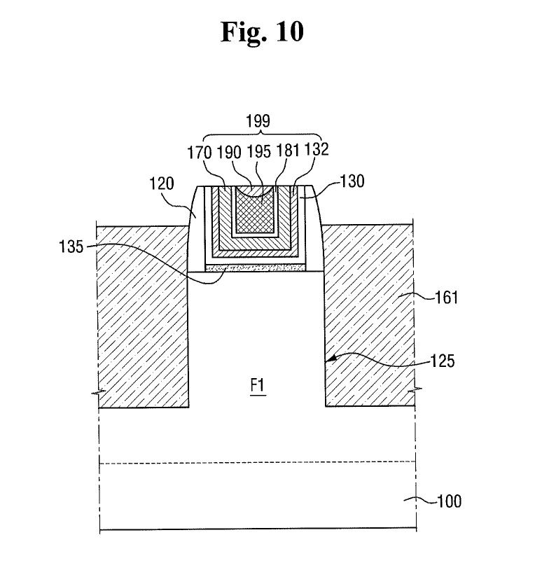

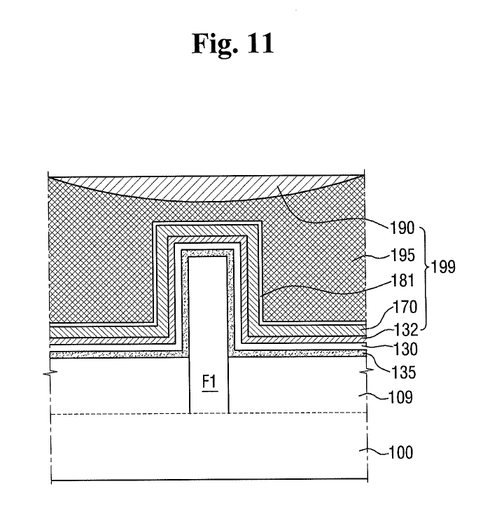

FIGS. 9 through 11 illustrate views of a semiconductor device according to a sixth example embodiment. FIG. 9 illustrates a perspective view of a semiconductor device according to a sixth example embodiment. FIG. 10 illustrates a cross-sectional view corresponding to line E-E of FIG. 9. FIG. 11 illustrates a cross-sectional view corresponding to line D-D of FIG. 9. FIGS. 9 through 11 illustrate views of a fin-type transistor which is replaced from the NMOS transistor described referring to FIGS. 1 through 4.

Referring to FIGS. 9 through 11, a semiconductor device 6 according to the sixth example embodiment may include a fin F1, a device isolation region 109, a spacer 120, a first metal gate electrode 199, a source/drain region 161, and a channel.

The fin F1 may extend to a second direction Y1. The fin F1 may be a part of the substrate 100 or an epitaxial layer which is grown from the substrate 100. The device isolation region 109 may cover a lower sidewall portion of the fin F1. The first metal gate electrode 199 crossing the fin F1 may be formed on the fin F1. The first metal gate electrode 199 may extend to the first direction X1. The first metal gate electrode 199 may include a lower metal layer 132, an N-type work function control layer 170, a first wetting layer 181, a first reactive layer 195, and a first gap fill layer 190.

The source/drain region 161 may be formed in the fin F1 which is adjacent sidewalls of the first metal gate electrode 199. The source/drain region 161 may have an elevated source/drain shape. The source/drain region 161 may be separated from the first metal gate electrode 199 by the gate spacer 120.

In the case of an NMOS transistor, the source/drain region 161 may include a material which may induce a tensile stress to the channel of the NMOS transistor. The source/drain region 161 may also include a substantially the same material with the substrate 100. For example, if the substrate 100 includes silicon (Si), the source/drain region 161 may include silicon carbide (SiC) which has a lattice constant less than that of silicon (Si).

In the case of a PMOS transistor, the source/drain region 161 may include a material which may induce a compressive stress to the channel of the PMOS transistor. For example, if the substrate 100 includes silicon (Si), the source/drain region 161 may include silicon germanium (SiGe) which has a lattice constant greater than that of silicon (Si).

The semiconductor device 5 according to the fifth example embodiment shown in FIG. 8A may be also applied to a fin-type transistor.

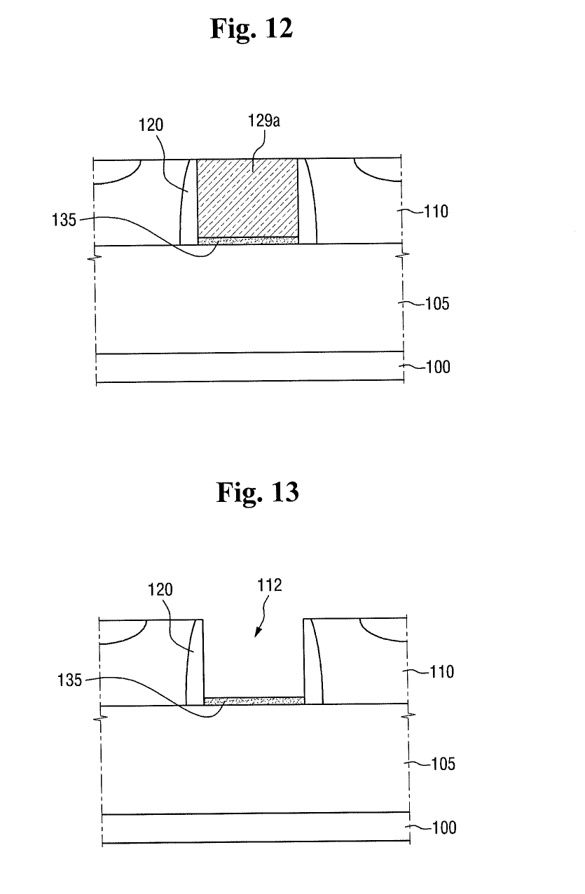

From now on, a method of manufacturing the semiconductor device according to the first example embodiment will be disclosed referring to FIGS. 1 through 4, and FIGS. 12 through 20. FIGS. 12 through 20 illustrate cross-sectional views of a method of manufacturing a semiconductor device according to the first example embodiment.

Referring to FIG. 12, a device isolation region 105 may be formed in a substrate 100. The device isolation region 105 may define an active region 103. A first interface layer 135 and a first dummy gate layer 129a may be formed on the substrate 100 and on the substrate 100.

The first interface layer 135 may be formed by using an atomic layer deposition process or chemical vapor deposition process. The first dummy gate layer 129a may include silicon (Si). For example, the first dummy gate layer 129a may include polysilicon, amorphous silicon, or a mixture thereof. The first dummy gate layer 129a may or may not include impurity. The impurity may be an N-type impurity, e.g., arsenic (As) or phosphorus (P), or a P-type impurity, e.g., boron (B).

A spacer 120 may be formed on sidewalls of the first dummy gate layer 129a. A source/drain region may be formed in the active region 103 which is adjacent sidewalls of the first dummy gate layer 129a.

An interlayer insulating layer 110 covering the first dummy gate layer 129a may be formed on the first and second substrates 100 and 200. The interlayer insulating layer 110 may include one or more of an oxide layer, a silicon nitride layer (SiN), or a silicon oxynitride layer (SiON). The interlayer insulating layer 110 may be a layer having a lower dielectric constant. In an embodiment, the interlayer insulating layer 110 may be formed by a process of FOX (Flowable Oxide), TOSZ (Tonen SilaZen), USG (Undoped Silica Glass), BSG (Boro-Silicate Glass), PSG (Phospho-Silacate Glass), BPSG (Boro-Phospho-Silicate Glass), PRTEOS (Plasma Enhanced Tetra Ethyl Ortho Silicate), FSG (Fluoride Silicate Glass), HDP (High Density Plasma), PEOX (Plasma Enhanced Oxide), FCVD (Flowable CVD), or any combination thereof.

The interlayer insulating layer 110 may be planarized by using a planarization process, e.g., a chemical mechanical polishing (CMP) process, to expose an upper surface of the first dummy gate layer 129a.

Referring to FIG. 13, the first dummy gate layer 129a may be removed. The first interface layer 135 may be removed and a second interface layer may be formed on the substrate 100. In an embodiment, the first interface layer 135 may be not removed.

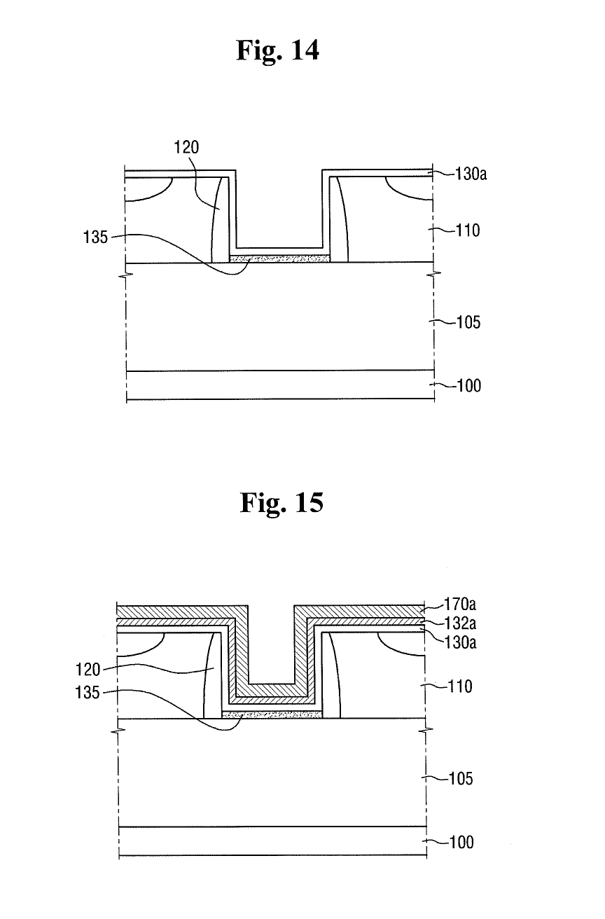

Referring to FIG. 14, a first dielectric layer 130a may be conformally formed on an upper surface of the interlayer insulating layer and in the first trench 112. The first dielectric layer 130a may be conformally formed along sidewalls and a bottom of the first trench 112. The first dielectric layer 130a may be formed by using a chemical vapor deposition (CVD) process or an atomic layer deposition (ALD) process.

Referring to FIG. 15, a lower metal layer 132a may be formed on the first dielectric layer 130a. An N-type work function control layer 170a may be formed on the lower metal layer 132a. The N-type work function control layer 170a may be conformally formed on an upper surface of the interlayer insulating layer 110 and along the sidewalls and the bottom of the first trench 112.

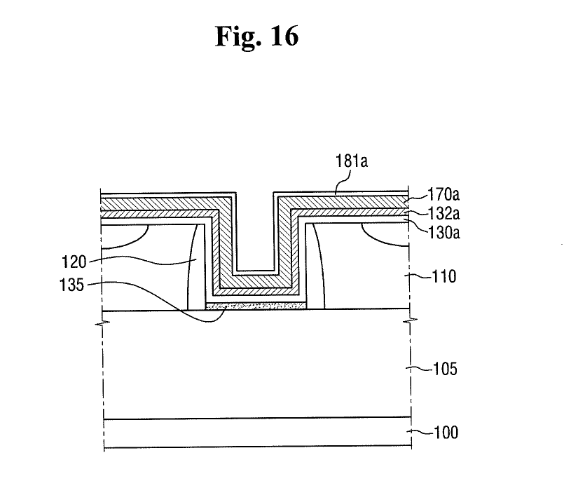

Referring to FIG. 16, a first wetting layer 181a may be formed on the N-type work function control layer 170a. The first wetting layer 181a may be formed on an upper portion of the interlayer insulating layer 110 and along the sidewalls and the bottom of the first trench 112.

The first wetting layer 181a may be formed by two-step deposition method. The two-step deposition method may include a first operation of forming a first portion of the wetting layer by using a direct current (DC) and a second operation of forming a second portion of the wetting layer on the first portion thereof by using an alternating current (AC). The first and second portions of the wetting layer 181a may have a thickness of about 10 angstrom to about 100 angstrom, respectively. A power ratio of the direct current by the alternating current (DC/AC) may be greater than 0 but less than or equal to 3.

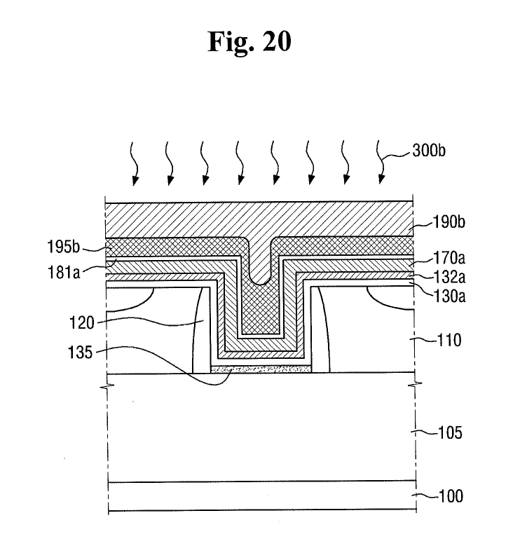

Using the two-step deposition method as described above, it may be possible to prevent formation of an overhang at an entrance of the first trench 112. It may be helpful to form a first reactive layer 195 and a gap fill layer without voids (see FIG. 20).

The first wetting layer 181a may include one or more of titanium (Ti) or titanium nitride (TiN).

Referring to FIG. 17, a first gap fill layer 190a may be formed on the first wetting layer 181a. The first gap fill layer 190a may have a first thickness of about 200 angstrom to about 500 angstrom.

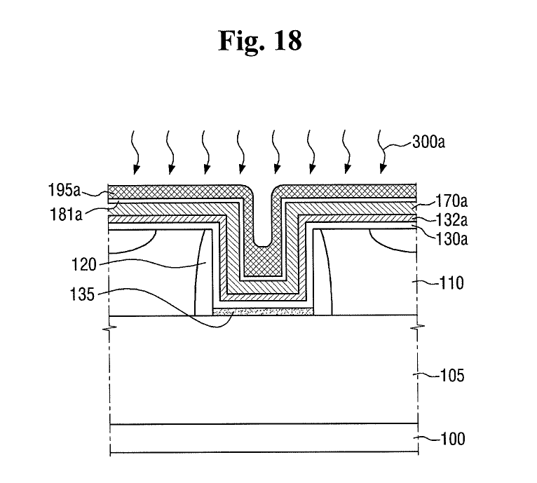

Referring to FIG. 18, a first heat treatment may be performed after forming the first gap fill layer 190a. The first heat treatment may be performed at a temperature of about 350° C. to about 450° C., and for about 1 second to about 300 second. For example, the first heat treatment may be performed for about 50 second.

A first reactive layer 195a may be formed by a chemical reaction between the first wetting layer 181a and the first gap fill layer 190a during the first heat treatment.

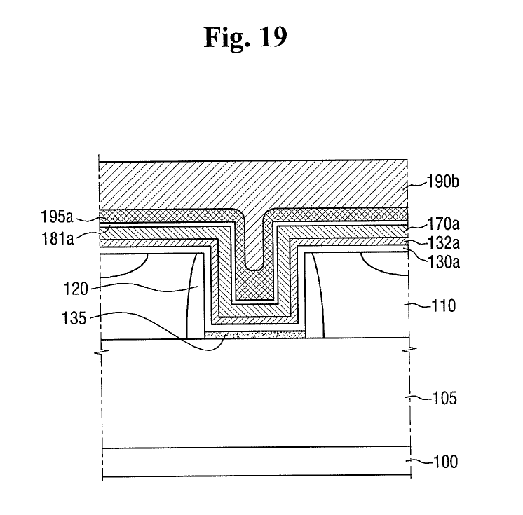

Referring to FIG. 19, a second gap fill layer 190b may be formed on the first reactive layer 195a. The second gap fill layer 190b may fully fill the first trench 112. A second thickness of the second gap fill layer 190b may be greater than the first thickness of the first gap fill layer 190a. For example, the second thickness may be from about 1000 angstrom to about 1500 angstrom.

Referring to FIG. 20, a second heat treatment 300b may be performed after forming the second gap fill layer 190b. The second heat treatment may be performed at a temperature of about 350° C. to about 450° C., e.g., 400° C., and for about 1 second to about 300 second, e.g., about 50 second.

A second reactive layer 195b may be formed by a chemical reaction between the first wetting layer 181a (or the first reactive layer 195a) and the second gap fill layer 190b during the second heat treatment.

The forming of the first gap fill layer 190a, the performing of the first heat treatment 300a, the forming of the second gap fill layer 190b, and the performing of the second heat treatment may be proceeded in-situ.

In other example embodiment, the forming of the first gap fill layer 190a may be proceeded at a temperature range of about 250° C. to about 350° C. and the performing of the first heat treatment 300a, the forming of the second gap fill layer 190b, and the performing of the second heat treatment may be proceeded at a temperature range of about 350° C. to about 450° C. The performing of the first heat treatment 300a, the forming of the second gap fill layer 190b, and the performing of the second heat treatment may be proceeded at the same temperature range.

In other example embodiment, the forming of the first gap fill layer 190a and the forming of the second gap fill layer 190b may be proceeded at a lower temperature than those of the performing of the first heat treatment 300a and the performing of the second heat treatment 300b. For example, the forming of the first gap fill layer 190a and the forming of the second gap fill layer 190b may be proceeded at a temperature range of about 250° C. to about 350° C., and the performing of the first heat treatment 300a and the performing of the second heat treatment 300b may be proceeded at a temperature range of about 350° C. to about 450° C.

In other example embodiment, the performing of the first heat treatment 300a and the performing of the second heat treatment 300b may be proceeded at a different temperature range. For example, the performing of the first heat treatment 300a may be proceeded at a higher temperature range than the performing of the second heat treatment 300b.

Referring to FIGS. 1 through 4 again, a planarization process may be performed to expose an upper surface of the interlayer insulating layer 110.

The first reactive layer 195 may be formed between the wetting layer 181 and the first gap fill layer 190, and the first gap fill layer 190 may not directly contact the first wetting layer 181. As shown in FIG. 4, the first gap fill layer 190 having an island shape may remain in the first reactive layer 195 after the planarization process. The first gap fill layer 190 may extend to the length direction of the metal gate electrode 199. Almost all of an unreacted portion of the first gap fill layer 190 may be removed by performing the planarization process, and a little, e.g., small, portion of the first gap fill layer 190 may remain.

Referring to FIGS. 8 and 21 through 26, a method of manufacturing a semiconductor device according to the fifth example embodiment will be disclosed.

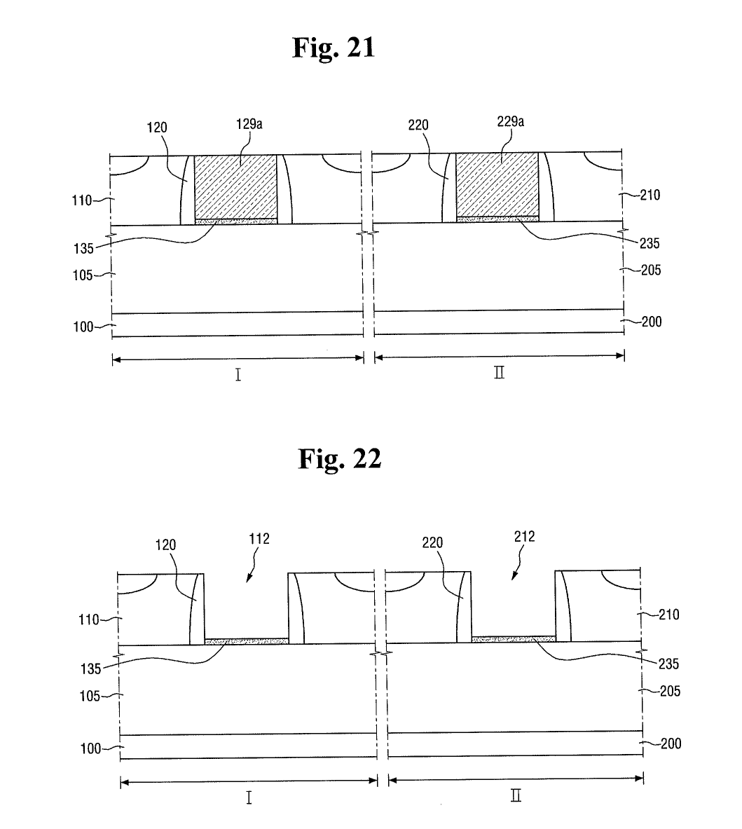

FIGS. 21 through 26 illustrate cross-sectional views of a method of manufacturing a semiconductor device according to the fifth example embodiment. For convenience of explanation, some of descriptions which are substantially the same as those corresponding to FIGS. 12 through 20 will be omitted.

Referring to FIG. 21, a first substrate 100 may include a first region I and a second substrate 200 may include a second region II. The first region I may contact or be separated from the second region II. The first region I may be an NMOS transistor region and the second region II may be a PMOS transistor region.

A first interface layer 135 and a first dummy gate layer 129a may be formed in the first region I of the first substrate 100. A second interface layer 235 and a second dummy gate layer 229a may be formed in the second region II of the second substrate 200.

A source/drain region may be formed both sides of the first and second dummy gate layers 129a and 229a, respectively. A first interlayer insulating layer 110 may be formed on the first dummy gate layer 129a and a second interlayer insulating layer 210 may be formed on the second dummy gate layer 129a. The first and second interlayer insulating layers may be planarized to expose the first and second dummy gate electrode layers 129a and 229a.

Referring to FIG. 22, the first and second dummy gate layers 129a and 229a may be removed.

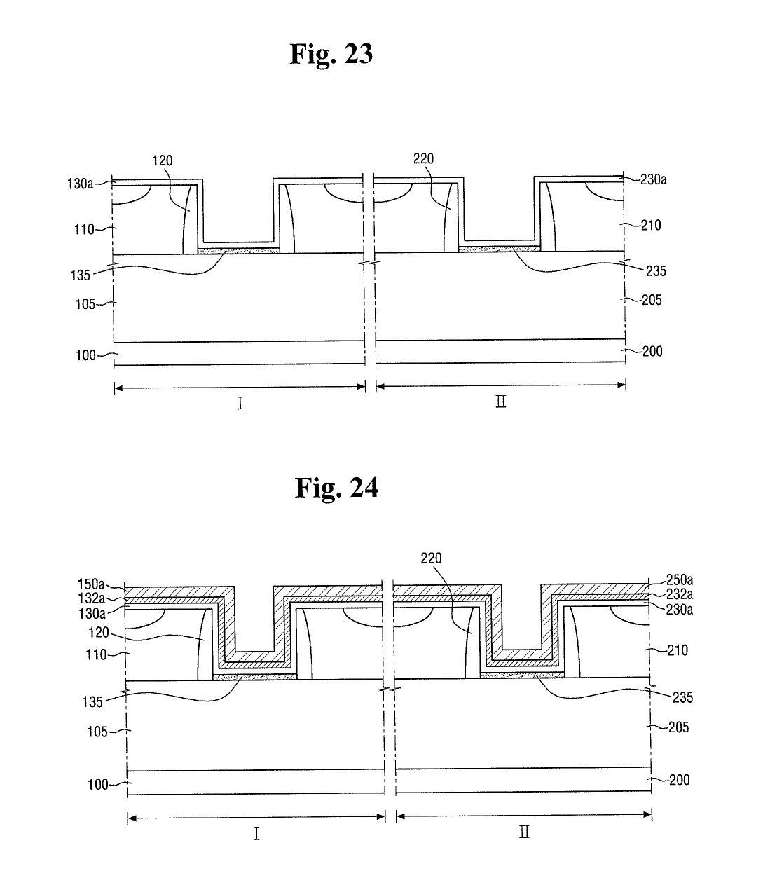

Referring to FIG. 23, a first dielectric layer 130a may be conformally formed on the first interlayer insulating layer 110 and along sidewalls and a bottom of the first trench 112 and a second dielectric layer 230a may be conformally formed on the second interlayer insulating layer 210 and along sidewalls and a bottom of the second trench 212.

Referring to FIG. 24, a first lower metal layer 132a and a first P-type work function control layer 150a may be conformally formed on the first dielectric layer 130a and along the sidewalls and the bottom of the first trench 112 and a second lower metal layer 232a and a second P-type work function control layer 250a may be conformally formed on the second dielectric layer 230a and along the sidewalls and the bottom of the second trench 212. The first and second P-type work function control layers 150a and 250a may be formed simultaneously and be formed of the same material.

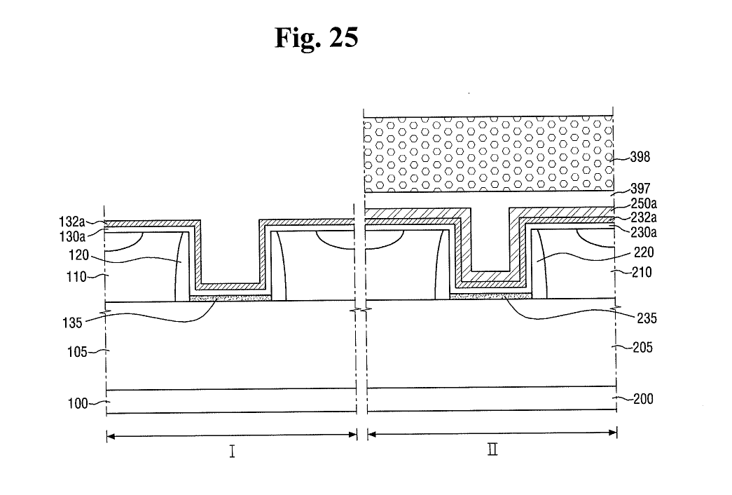

Referring to FIG. 25, a mask pattern 397 and a photoresist pattern 398 may be formed on the second P-type work function control layer 250a which may be formed in the second region II, and the first P-type work function control layer 150a may be exposed in the first region I. The mask pattern 397 may include a bottom anti-reflective coating (BARC) layer.

The method of forming the mask pattern 397 and the photoresist pattern 398 may be described in detail.

A mask layer filling the first and second trenches 112 and 212 may be formed on the first and second P-type work function control layers 150a and 250a formed in the first and second regions I and II, respectively. The photoresist pattern 398 exposing the first region I may be formed on the mask layer formed in the second region II. The mask layer formed in the first region I may be removed by using a dry etching process, e.g., a reactive ion etching (RIE) process. At this moment, the photoresist pattern 398 may be used as an etch mask. The dry etching process may be performed by using an etching gas comprising oxygen (O). The etching gas may include chlorine (Cl). The etching gas may further include helium (He).

In the etching gas, a fraction of oxygen may be a first fraction, a fraction of chlorine may be a second fraction, and a fraction of helium may be a third fraction. The second fraction may be greater than the first fraction. For example, a ratio of the second fraction of chlorine with respect to the first fraction of oxygen may have a value of from about 1.1 to about 7.

The third fraction may be greater than the first fraction or the second fraction. For example, the third fraction of helium may be greater than the sum of the first fraction of oxygen and the second fraction of chlorine.

When the mask layer formed in the first region I is removed by using the reactive ion etching (RIE) process, a bias voltage may be induced to the first and second substrates 100 and 200. In an embodiment, the bias voltage may be from about 10V to about 300V.

A power for generating plasma may be induced during the reactive ion etching (RIE) process. In an embodiment, the power may be from about 50 W to about 600 W.

In another example embodiment, the mask layer formed in the first region I may be removed by using a mixed gas comprising nitrogen and hydrogen to form the mask pattern 397.

The first P-type work function control layer 150a may be removed by an etch process using the mask pattern 397 as an etching mask, and the first lower metal layer 132a may be exposed. The first P-type work function control layer 150a may be removed by using a wet etching process. In an embodiment, the wet etching process may be performed by using a wet chemical comprising hydrogen peroxide (H₂O₂).

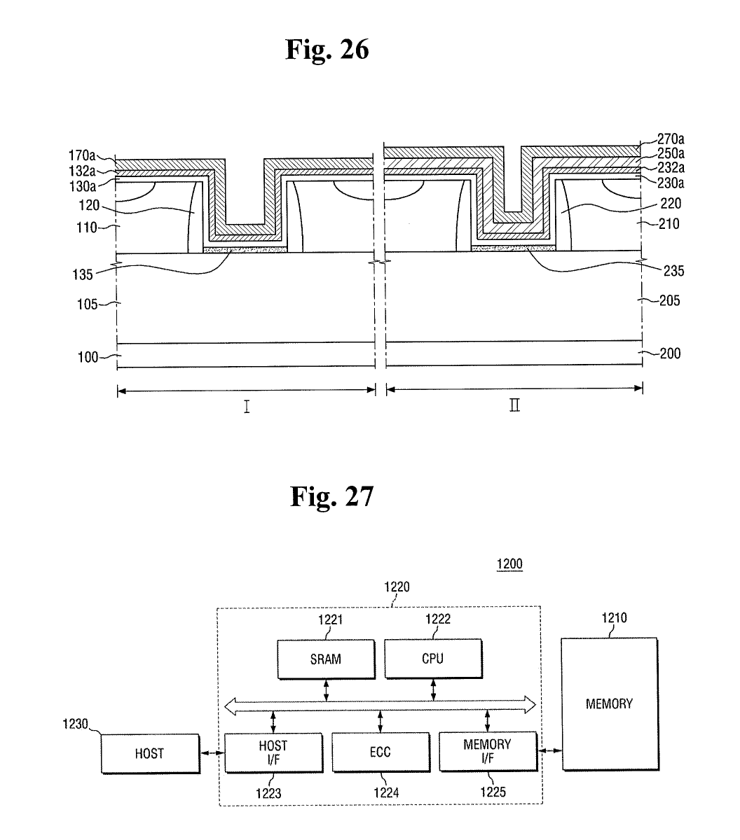

Referring to FIG. 26, the mask pattern 397 and the photoresist pattern 398 may be removed by performing an ashing/strip process using a mixed gas comprising hydrogen and nitrogen, and the second P-type work function control layer 250a may be exposed.

First and second N-type work function control layers 170a and 270a may be formed in the first and second regions I and II, respectively. The first and second N-type work function control layers 170a and 270a may be formed simultaneously and be formed of the same material.

The following processes may be substantially the same as the descriptions referring to FIGS. 16 through 20. A wetting layer may be formed on the first and second N-type work function layers 170a and 270a. A first gap fill layer may be formed on the wetting layer and a first heat treatment may be performed. A second gap fill layer may be formed on the result surface and a second heat treatment may be performed. A reactive layer may be formed between the wetting layer and the first gap fill layer through the first and second heat treatments.

Referring to FIG. 8 again, the semiconductor device according to the fifth example embodiment may be formed after performing a planarization process to expose an upper surface of the first and second interlayer insulating layers 110 and 210.

FIG. 27 illustrates a block diagram of a memory card 1200 including a semiconductor device according to an example embodiment.

Referring to FIG. 27, the memory card 1200 may include a memory 1210 having one of the semiconductor devices according to the various example embodiments as mentioned above. The memory card 1200 may include a memory controller 1220 controlling data exchange between a host 1230 and the memory 1210. The memory controller may include a static random access memory (SRAM), a central processing unit (CPU) 1222, a host interface 1223, an error correction code (ECC) 1224, and a memory interface 1225. The SRAM 1221 may be used as a memory device of the CPU 1222. The host interface 1223 may include a protocol for exchange data between the host 1230 and the memory card 1200. The ECC 1224 may detect and correct errors in data read out from the memory 1210. The memory interface 1225 may interface with the memory 1210. The CPU 1222 may control overall action relating to data exchange of the memory controller 1220.

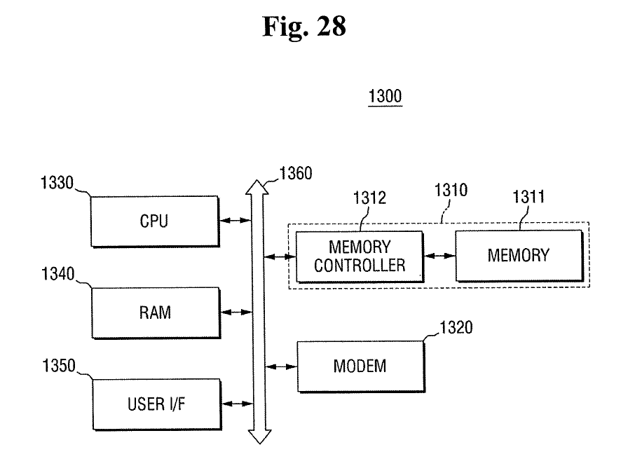

FIG. 28 illustrates a block diagram of an information processing system including a semiconductor device according to an example embodiment. Referring to FIG. 28, the information processing system 1300 may include a memory system 1310 including one of the semiconductor devices according to the various example embodiments as mentioned above. The memory system 1310 may be connected with a system bus 1360. The information processing system 1300 may further include a modem 1320, a central processing unit (CPU) 1330, a random access memory (RAM) 1340, and a user interface 1350 which are connected with the system bus 1360. The memory system 1310 may include a memory 1311 and a memory controller 1312. The memory controller 1312 may have substantially the same structure as the memory controller 1220 as shown in FIG. 27. A data processed by the CPU 1330 or received from an external device may be stored in the memory system 1310. The information processing system 1300 may be applied to a memory card, a solid state drive (SSD), a camera image sensor, or other various chipsets.

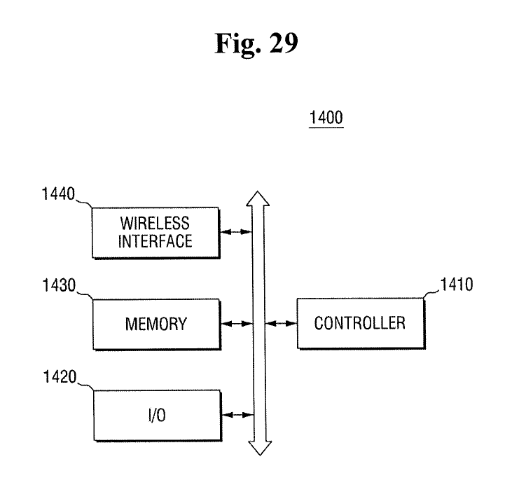

FIG. 29 illustrates a block diagram of an electronic device including a semiconductor device according to an example embodiment. Referring to FIG. 29, an electronic device 1400 may include a controller 1410, an input/output device 1420, a memory 1430, and a wireless interface 1440. The controller 1410, the input/output device 1420, the memory 1430, and the wireless interface 1440 may communicate with each other through a bus system.

The controller 1410 may include a microprocessor, a digital signal processor, a microcontroller, or a similar device that can control an executive program. The input/output device 1420 may include a keypad, a keyboard, or a display. The memory 1430 may not only save codes or data for executing the controller 1410 but also save data executed by the controller 1410. The memory 1430 may include a semiconductor device according to an example embodiment. The wireless interface 1440 may transfer data to or from a communication network. The wireless interface 1440 may include an antenna or a wireless transceiver.

The electronic device 1400 may be applied to various products that can transport information or data, e.g., an ultra mobile personal computer, a work station, a PDA (personal digital assistant), a portable computer, a web tablet, a wireless phone, a mobile phone, a smart phone, an e-book, a portable multimedia player, a portable game device, a navigation system, a black box, a digital camera, a three dimensional television, a digital audio recorder, a digital audio player, a digital picture player, a digital video recorder, or a digital video player.

By way of summation and review, metal gate electrodes may include aluminum (Al). The aluminum (Al) can be subject to being diffused to a high-k dielectric layer during a subsequent heat treatment. This, in turn, may damage the high-k dielectric layer and may decrease performance of semiconductor devices. For example, threshold voltages (Vth) of the semiconductor devices may be changed.

Provided is a semiconductor device having a work function control layer and a method of manufacturing the same. According to embodiments, diffusion of aluminum (Al) into a high-k dielectric layer during a replacement metal gate (RMG) process may be prevented.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor device, comprising:
a substrate;
an interlayer insulating layer having a trench on the substrate, the trench having a bottom and sidewalls;
a dielectric layer on the bottom and sidewalls of the trench;
a work function control layer on the dielectric layer;
a wetting layer on the work function control layer;
a gap fill layer on the wetting layer; and
a reactive layer between the wetting layer and the gap fill layer,
the reactive layer being thicker than the gap fill layer.

2. The semiconductor device as claimed in claim 1, wherein the wetting layer includes titanium (Ti) and the gap fill layer includes aluminum (Al).

3. The semiconductor device as claimed in claim 2, wherein the reactive layer includes titanium aluminum (TiₓAl_{y}).

4. The semiconductor device as claimed in claim 2, wherein the reactive layer includes one or more of TiAl, TiAl₃, TiAlO, or TiAlN.

5. The semiconductor device as claimed in claim 1, wherein the work function control layer includes an N-type work function control layer.

6. The semiconductor device as claimed in claim 1, further comprising an interface layer between the substrate and the dielectric layer.

7. A semiconductor device, comprising:
a first device; and
a second device,
the first device including:
a first interlayer insulating layer having a first trench, the first trench having a bottom and sidewalls;
a first dielectric layer on the bottom and sidewalls of the first trench;
a first work function control layer on the first dielectric layer;
a first wetting layer on the first work function control layer;
a gap fill layer on the first wetting layer; and
a first reactive layer between the first wetting layer and the gap fill layer, the first reactive layer being formed by a reaction of the first wetting layer and the gap fill layer, the second device including:
a second interlayer insulating layer having a second trench, the second trench having a bottom and sidewalls;
a second dielectric layer on the bottom and sidewalls of the second trench;
a second work function control layer on the second dielectric layer;
a second wetting layer on the second work function control layer; and
a second reactive layer on the second wetting layer.

8. The semiconductor device as claimed in claim 7, wherein:
the first and second wetting layers include titanium (Ti); and
the gap fill layer includes aluminum (Al).

9. The semiconductor device as claimed in claim 8, wherein the first and second reactive layers include titanium aluminum (TiₓAl_{y}).

10. The semiconductor device as claimed in claim 8, wherein the first and second reactive layers include one or more of TiAl, TiAl₃, TiAlO, or TiAlN.

11. The semiconductor device as claimed in claim 7, further comprising a third work function control layer between the second dielectric layer and the second work function control layer.

12. The semiconductor device as claimed in claim 11, wherein:
the first and second work function control layers are N-type work function control layers; and
the third work function control layer is a P-type work function layer.

13. The semiconductor device as claimed in claim 7, wherein:
the first work function control layer is an N-type work function control layer; and
the second work function control layer is a P-type work function layer.

14. The semiconductor device as claimed in claim 13, wherein the first reactive layer is thicker than the gap fill layer.

15. The semiconductor device as claimed in claim 7, wherein the first device is a N-type metal-oxide semiconductor (NMOS) and the second device is a P-type metal-oxide semiconductor (PMOS).

16.-33. (canceled)

34. A semiconductor device, comprising:
an interlayer insulating layer having a trench on a substrate, the trench having a bottom and sidewalls;
a dielectric layer on the bottom and sidewalls of the trench, the dielectric layer having a dielectric constant greater than that of a silicon oxide layer;
a work function control layer on the dielectric layer;
a wetting layer on the work function control layer;
a gap fill layer on the wetting layer; and
a reactive layer between the wetting layer and the gap fill layer, the reactive layer including a first material included in the wetting layer and a second material included in the gap fill layer.

35. The semiconductor device as claimed in claim 34, wherein the first material is titanium (Ti) and the second material is aluminum (Al).

36. The semiconductor device as claimed in claim 34, wherein the reactive layer includes titanium aluminum (TiₓAl_{y}).

37. The semiconductor device as claimed in claim 34, wherein the reactive layer includes one or more of TiAl, TiAl₃, TiAlO, or TiAlN.

38. The semiconductor device as claimed in claim 35, wherein the reactive layer is a diffusion preventing layer preventing aluminum from diffusing into the dielectric layer from the gap fill layer.
